(19) United States
(12) Patent Application Publication
(10) Pub. No.: US 2020/0098957 A1
(43) Pub. Date: Mar. 26, 2020

(54) MULTIPLE LED LIGHT SOURCE LENS DESIGN IN AN INTEGRATED PACKAGE

(71) Applicant: CREE HUIZHOU SOLID STATE LIGHTING COMPANY LTD., Huizhou, Guangdong (CN)

(72) Inventors: Chak Hau Charles PANG, Fanling, NT (HK); Yue Kwong Victor LAU, Laguna City Kowloon (HK); JuZuo SHENG, Huizhou City, Guangdon (CN); Christopher P. HUSSELL, Cary, NC (US)

(21) Appl. No.: 16/472,500

(22) PCT Filed: Jan. 17, 2017
(86) PCT No.: PCT/CN2017/071481

§ 371 Date: Jun. 21, 2019

(51) Int. Cl. H01L 33/58; H01L 25/075; H01L 33/60; H01L 33/62; H01L 33/48; H01L 25/13

(52) U.S. Cl. CPC H01L 33/58; H01L 25/0753; H01L 25/13; H01L 33/62; H01L 33/486; H01L 33/60

(57) ABSTRACT

Light emitting diode (LED) packages and LED displays utilizing the LED packages are disclosed. LED packages can have a cavity with emitters arranged in close proximity to approximate a point light source, with each of the packages emitting a color combination of light from the emitters. The LED packages are arranged with an encapsulant or lens over the cavity that shapes the LED package emission to a wide angle or pitch. One embodiment of an LED package according to the present invention comprises a cavity with a plurality LEDs. The LED package also comprises a lens over the cavity to shape the emission of the LEDs to a wider angle along an axis compared to emission of the LEDs without the lens. The LEDs are individually controllable, with the LED package emitting different color combinations of emission from the LEDs. One embodiment of an LED display according to the present invention comprises a plurality of LED packages, at least some having a cavity with a plurality of LEDs. Each of the packages comprises a lens over each cavity to produce an emission of the LEDs that has a wider angle compared to the emission without the lens. The LED packages are mounted within the display to generate a wide angle image.

### CROSS REFERENCE TO RELATED APPLICATIONS

This national phase application claims priority to International Application No. PCT/CN2017/071481, having the same title and filed on Jan. 18, 2017.

### BACKGROUND OF THE INVENTION

### Field of the Invention

This invention relates to light emitting diodes (LED or LEDs) and in particular displays utilizing LEDs.

### Description of the Related Art

Light emitting diodes (LED or LEDs) are solid state devices that convert electric energy to light, and generally comprise one or more active layers of semiconductor material sandwiched between oppositely doped layers. When a bias is applied across the doped layers, holes and electrons are injected into the active layer where they recombine to generate light. Light is emitted from the active layer and from all surfaces of the LED.

Technological advances over the last decade or more has resulted in LEDs having a smaller footprint, increased emitting efficiency, and reduced cost. LEDs also have an increased operation lifetime compared to other emitters. For example, the operational lifetime of an LED can be over 50,000 hours, while the operational lifetime of incandescent bulb is approximately 2,000 hours. LEDs can also be more robust than other light sources and can consume less power. For these and other reasons, LEDs are becoming more popular and are now being used in more and more applications that have traditionally been the realm of incandescent, fluorescent, halogen and other emitters.

LEDs are now being used in displays, both big and small. Large screen LED based displays (often referred to as giant screens) are becoming more common in many indoor and outdoor locations, such as at sporting events, race tracks, concerts and in large public areas such as Times Square in New York City. Many of these displays or screens can be as large as 60 feet tall and feet wide, or larger. These screens can comprise thousands of “pixels” mounted on a flat surface to generate an image, with each pixel containing a plurality of LEDs. The pixels can use high efficiency and high brightness LEDs that allow the displays to be visible from relatively far away, even in the daytime when subject to sunlight. The pixels can have as few as three or four LEDs (one red, one green, and one blue) that allow the pixel to emit many different colors of light from combinations of red, green and/or blue light. In the largest giant screens, each pixel module can have more than three LEDs, with some having dozens of LEDs. The pixels can be arranged in a rectangular grid with the size and density of the screen determining the number of pixels. For example, a rectangular display can be 640 pixels wide and 480 pixels high, with the end size of the screen being dependent upon the actual size of the pixels.

Conventional LED based displays are controlled by a computer system that accepts an incoming signal (e.g. TV signal) and based on the particular color needed at the pixel module to form the overall display image, the computer system determines which LED in each of the pixel modules is to emit light and how brightly. A power system can also be included that provides power to each of the pixel modules and the power to each of the LEDs can be modulated so that it emits at the desired brightness. Conductors are provided to apply the appropriate power signal to each of the LEDs in the pixel modules.

Some large LED displays are arranged for wide angle or wide pitch emission that allows for a wide lateral range of viewing angles. Pixels for conventional wide angle displays can use oval lamp LEDs, with some using 3 lamps for each pixel. FIG. 1 shows one embodiment of conventional red, green and blue LEDs 12, 14 and 16 that can be used to form a pixel in a display, and FIG. 2 shows a conventional pixel 10 that includes the red, green and blue LEDs 12, 14, 16 that are mounted to a substrate 18 using conventional through-hole techniques. Each of the LED lamps 12, 14, 16 has an oval shaped lens to produce a wider angle emission pattern compared to lamps with a circular lens. Fabricating giant screens with three or more separate LED lamps per pixel can be costly and complicated.

FIG. 3 shows the red LED lamp emission pattern 20, the green LED lamp emission pattern 22 and the blue LED lamp emission pattern 24 from the LEDs 12 14, 16. The spacing of the LED lamps 12, 14, 16 as shown in FIG. 2 can result in each of the emission patterns offset from the pixel center point 26. This offset can inhibit pixel color mixing, particularly in the far field. FIG. 4 is a graph 30 showing one example of the emission pattern for a conventional pixel showing the emissions from red LED 32, the green LED 34 and the blue LED 36. The emissions do not fully overlap, which can result in less than optimal color mixing in the far field.

### SUMMARY OF THE INVENTION

The present invention is directed to LED packages and LED displays utilizing the LED packages, with some embodiments comprising high-density LED displays. The present invention is particularly applicable to LED packages having a cavity with emitters arranged in close proximity to one another to approximate a point light source, with each of the packages emitting a color combination of light from the emitters. The LED packages are arranged with an encapsulant or lens over the cavity that helps shape the LED package emission to a wide angle or pitch.

One embodiment of an LED package according to the present invention comprises a cavity with a plurality of LEDs, wherein the cavity reflects light from the LEDs to contribute to the emission of the package. The LED package also comprises a lens over the cavity to shape the emission of the LEDs compared to emission of the LEDs without the lens. Leads and/or wire bonds are included to each of the LEDs to individually control the emission of each of the LEDs, with the LED package emitting different color combinations of emission from the LED.

One embodiment of an LED display according to the present invention comprises a plurality of LED packages, at least some having a cavity with a plurality of LEDs. Each of the packages comprises a lens over each cavity to produce an emission of the LEDs that has a wider angle compared to the emission without the lens. The LED packages are mounted within the display to generate a wide angle image. The wider angle can be on the horizontal viewing side and with the LED package emitting with control on the vertical viewing side. The lens and cavity arrangement can also enhance the LED packages emission efficiency, resulting in higher brightness.

Another embodiment of an LED package according to the present invention comprises an oval shaped cavity with a plurality LEDs. An oval shaped lens is included over the cavity to shape the emission of the LEDs to a wider angle compared to emission of the LEDs with a hemispheric lens or without the lens. The intensity of each of the LEDs can be individually controllable so that the LED package emits different color combinations of light from the LEDs.

These and other aspects and advantages of the invention will become apparent from the following detailed description and the accompanying drawings, which illustrate by way of example the features of the invention.

### BRIEF DESCRIPTION OF THE DRAWINGS

FIG. 1 is a side view of conventional light emitting diodes (LEDs) that can be used for pixels in a display;

FIG. 2 is a perspective view of the LEDs in FIG. 1 mounted in a display as one pixel;

FIG. 3 shows the individual emission patterns for the LEDs in FIG. 2;

FIG. 4 shows the overlap of the emissions for the LEDs in the pixel in FIG. 2;

FIG. 5 is a perspective view of one embodiment of an LED package according to the present invention;

FIG. 6 is a perspective view of another embodiment of an LED package according to the present invention;

FIG. 7 is a top view of the LED package in FIG. 6;

FIG. 8 is a perspective view of another embodiment of an LED package according to the present invention;

FIG. 9 is a top view of the LED package in FIG. 8;

FIG. 10 is a perspective view of another embodiment of an LED package according to the present invention;

FIG. 11 is a top view of the LED package in FIG. 10;

FIG. 12 is a perspective view of another embodiment of an LED package according to the present invention;

FIG. 13 is a perspective view of another embodiment of an LED package according to the present invention;

FIG. 14 is a perspective view of another embodiment of an LED package lens according to the present invention;

FIG. 15 is a perspective view of another embodiment of an LED package according to the present invention;

FIG. 16 is a side view of another embodiment of an LED package according to the present invention;

FIG. 17 is another side view of the LED package in FIG. 16;

FIG. 18 is a side view of another embodiment of an LED package according to the present invention;

FIG. 19 is another side view of the LED package in FIG. 18;

FIG. 20 is a graph showing emission patterns for one LED package according to the present invention taken along one axis;

FIG. 21 is another graph for the same LED package shown in FIG. 20, taken along an orthogonal axis;

FIG. 22 is a graph showing emission patterns for one LED package according to the present invention taken along one axis;

FIG. 23 is another graph for the same LED package shown in FIG. 22, taken along an orthogonal axis;

FIG. 24 is a perspective view of another LED package according to the present invention

FIG. 25 is a top view of another embodiment of an LED package according to the present invention;

FIG. 26 is a side view of the LED package shown in FIG. 25;

FIG. 27 is a top perspective view of the LED package shown in FIG. 25, with lenses in the cavities;

FIG. 28 is bottom perspective view of the LED package shown in FIG. 25;

FIG. 29 is a top view of another embodiment of an LED package according to the present invention;

FIG. 30 is a side view of the LED package shown in FIG. 29;

FIG. 31 is a top perspective view of the LED package shown in FIG. 29, with lenses in the cavities; and

FIG. 32 is bottom perspective view of the LED package shown in FIG. 29.

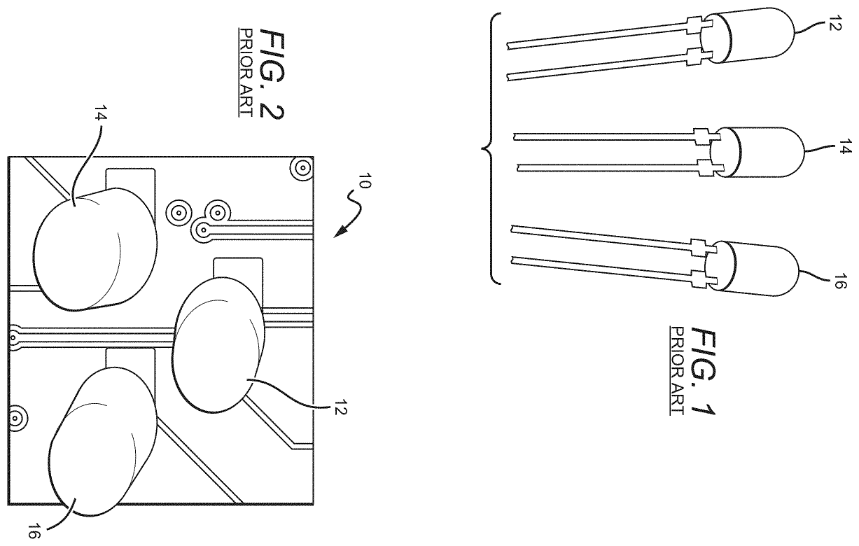

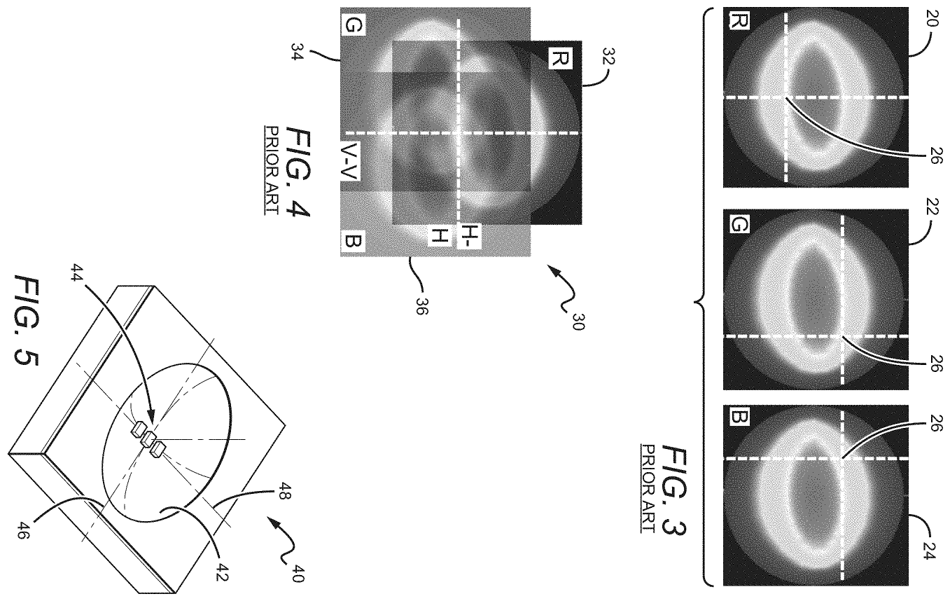

### DETAILED DESCRIPTION OF THE INVENTION

The present invention is directed to various embodiments of surface mount device (SMD) light emitting diode packages and displays using those packages. Each of the packages is arranged to be used for a single pixel, instead of the conventional LED displays that can use multiple LED or LED lamps per pixel. This can make manufacturing of the display easier and less expensive, can provide for display that is more reliable, and in some instances can result in higher density display.

In some embodiments, the LED packages according to the present invention can have an single oval shaped cavity or can have multiple oval shaped cavities. The cavities can have an oval shaped lens which can help shape the emission of the package to provide wide angle or wide pitch emission along an axis or centerline of the LED package compared to an LED package with circular cavity and hemispheric lens. This allows for displays using the LED packages to provide for a wider emission angle or pitch.

In some embodiments, the LED packages can have a plurality of LEDs mounted at or near the base of the cavity of a single, with the LEDs being relatively close to one another. This allows for the LEDs to approximate a point light source, which can result in improved color mixing particularly in the far field. This LED packages allows for good color mixing while still providing wide angle emission. In other embodiments, the LED packages can have a plurality of cavities, each having an LED that emits a different color of light. The LED package can emit light that is a combination of light from the different cavities, with the cavities approximating a light source.

In addition to the above advantages, the LED packages according to the present invention can be easier to handle compared to conventional LEDs, and can be easier to assemble into an LED display. The LED packages and resulting LED displays can provide improved emission while at the same time being more reliable and having longer life span.

The different embodiments according to the present invention can comprise different shapes and sizes of cavities, with some cavities having a curved surface while others can have an angled side surface and planar base. Solid state emitters are included at or near the center of the emitter base, with some embodiments having emitters that comprise light emitting diodes that emit the same or different colors of light. In some embodiments, the LEDs can comprise red, green and blue emitting LEDs that are individually controllable. The packages can emit different colors combinations of light from the LEDs depending on the intensity of each the respective LEDs. The LEDs are arranged in close proximity to one another to approximate a point light source. This can enhance color mixing and can improve the packages emission FFP.

The present invention is described herein with reference to certain embodiments, but it is understood that the invention can be embodied in many different forms and should not be construed as limited to the embodiments set forth herein. In particular, many different LED reflective cup and lead frame arrangements can be provided beyond those described herein, and the encapsulant can provide further features to alter the direction of emissions from the LED packages and LED displays utilizing the LED packages. Although the different embodiments of LED packages discussed below are directed to use in LED displays, they can be used in many other applications either individually or with other LED packages having the same or different peak emission tilt.

It is also understood that when an element such as a layer, region or substrate is referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one layer or another region. It is understood that these terms are intended to encompass different orientations of the device in addition to the orientation depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

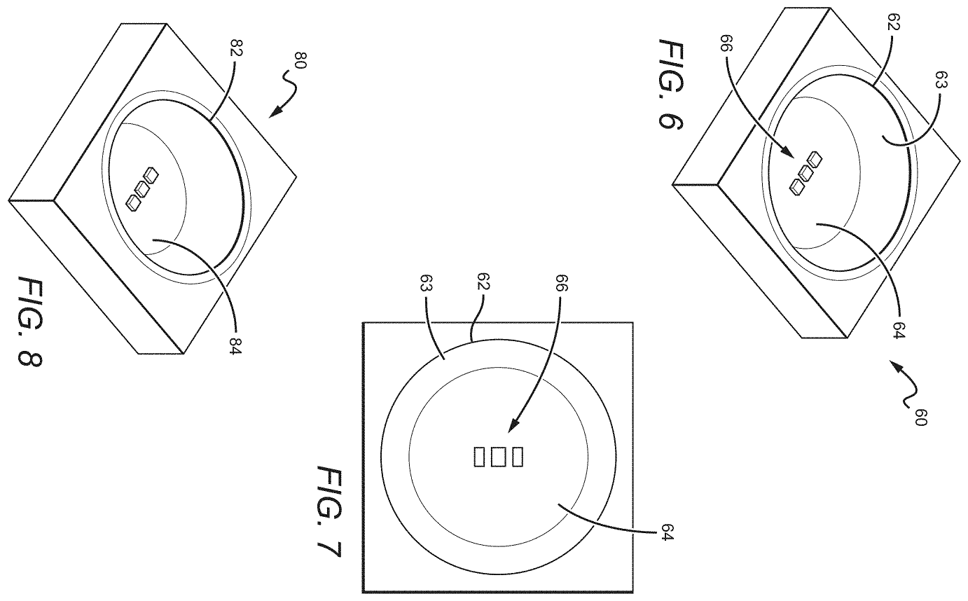

FIG. 5 shows one embodiment of an LED package 40 according to the present invention having an oval shaped cavity or reflective cup (“cavity) 42 with a plurality of emitters 44 at the base of the cavity 42. It is understood that most or all of the pixel modules in an LED display can comprise essentially the same or similar LED packages, and one embodiment of a display according to the present invention can comprise LED packages that are the same as or similar to the LED package 40. Each of the LED packages can be capable of emitting many different colors with the same or similar FFP, with the plurality of LED packages emitting light that combines to form the image projected by the display.

The emitters 44 can comprise a plurality of LEDs mounted at the base of the cavity 42 using known mounting methods. The cavity 42 can have many different shapes and sizes as described in more detail below, with the cavity 42 in the embodiment shown being oval shaped and having a curved surface to reflect side emitted light from the LED 42 in a direction to contribute to the desired emission from the LED package 40. All or some of the surfaces of the cavity are covered by a reflective material that also causes diffusion of the light, which helps in light mixing. In some embodiments, the surfaces can be covered by a flat white paint that is at least 90% reflective and is also diffusive.

Lead frames and/or wire bonds are included for applying an electrical signal to the emitters, and lens (not shown) can be formed in and over the cavity 42. In some embodiments the lead frame and wire bonds can be provided on a printed circuit board (PCB) with the cavity formed (such as by molding processes) on the PCB. The PCB can serve as the bottom surface of the cavity. In other embodiments, such as PLCC packages, the housing and cavity are formed (such as by molding processes) around a lead frame, with the lead frame being accessible at the base of the cavity. Is some embodiments, the lead frame can comprise a reflective material to reflect light emitted toward the lead frame so that the light can contribute to overall emission of the LED package.

In some embodiments, the lens can comprise a transparent material, such as an epoxy, that protects the LED, cavity and any electrical connections, and can shape the light emitting from the package 40. In other embodiments, the lens can comprise light conversion materials (such as phosphors), light scattering particles to mix the package light, and texturing to enhance light extraction. The lens can comprise many different shapes and sizes. In some embodiments, the lens can be dome shaped, while in other embodiments the lens can be oval shaped to match the shape of the cavity 42. Still in other embodiments, the lens can comprise a hybrid of different shapes, with one embodiment comprises in integration of 3 oval shapes with each of the ovals arranged to primarily enhance or shape light extraction from a respective one of the emitters 44.

The emitters 44 can comprise different types and different numbers of solid state emitters and the emitters can emit the same of different colors of light. In the embodiment shown package 40 comprises three solid state emitters with the first emitting red light, the second emitting green light and the third emitting blue light. The respective emitters in some embodiments can emit light of approximately 470 nm, 527 nm and 619 nm wavelength. The LEDs can have many different sizes and can emit many different emission patterns, with the preferred LED emitting a generally Lambertian emission pattern.

Each of the emitters can be individually controlled to emit different intensities, with the emissions from the emitters combining to emit different colors in the emission spectrum. It is understood that the emitters 44 can comprise more or less than three emitters, with some embodiments having 4, 8, 12 or more emitters. In the embodiment shown, the emitters 44 comprise three light emitting diodes (LEDs).

Fabrication of conventional LEDs is generally known, and is only briefly discussed herein. LEDS can be fabricated using known processes with a suitable process being fabrication using metal organic chemical vapor deposition (MOCVD). The layers of the LEDs generally comprise an active layer/region sandwiched between first and second oppositely doped epitaxial layers all of which are formed successively on a growth substrate. LEDs can be formed on a wafer and then singulated for mounting in a package. It is understood that the growth substrate can remain as part of the final singulated LED or the growth substrate can be fully or partially removed.

It is also understood that additional layers and elements can also be included in LEDs 48, including but not limited to buffer, nucleation, contact and current spreading layers as well as light extraction layers and elements. The active region can comprise single quantum well (SQW), multiple quantum well (MQW), double heterostructure or super lattice structures. The active region and doped layers may be fabricated from different material systems, with preferred material systems being Group-III nitride based material systems. Group-III nitrides refer to those semiconductor compounds formed between nitrogen and the elements in the Group III of the periodic table, usually aluminum (Al), gallium (Ga), and indium (In). The term also refers to ternary and quaternary compounds such as aluminum gallium nitride (AlGaN) and aluminum indium gallium nitride (AlInGaN). In a preferred embodiment, the doped layers are gallium nitride (GaN) and the active region is InGaN. In alternative embodiments the doped layers may be AlGaN, aluminum gallium arsenide (AlGaAs) or aluminum gallium indium arsenide phosphide (AlGaInAsP).

The growth substrate can be made of many materials such as sapphire, silicon carbide, aluminum nitride (AlN), gallium nitride (GaN), with a suitable substrate being a 4H polytype of silicon carbide, although other silicon carbide polytypes can also be used including 3C, 6H and 15R polytypes. Silicon carbide has certain advantages, such as a closer crystal lattice match to Group III nitrides than sapphire and results in Group III nitride films of higher quality. Silicon carbide also has a very high thermal conductivity so that the total output power of Group-III nitride devices on silicon carbide is not limited by the thermal dissipation of the substrate (as may be the case with some devices formed on sapphire). SiC substrates are available from Cree Research, Inc., of Durham, N.C. and methods for producing them are set forth in the scientific literature as well as in U.S. Pat. Nos. Re. 34,861; 4,946,547; and 5,200,022.

LEDs can also comprise a conductive current spreading structure and wire bond pads on the top surface, both of which are made of a conductive material that can be deposited using known methods. Some materials that can be used for these elements include Au, Cu, Ni, In, Al, Ag or combinations thereof and conducting oxides and transparent conducting oxides. The current spreading structure can comprise conductive fingers arranged in a grid on LEDs 48 with the fingers spaced to enhance current spreading from the pads into the LED's top surface. In operation, an electrical signal is applied to the pads through a wire bond as described below, and the electrical signal spreads through the fingers of the current spreading structure and the top surface into the LEDs. Current spreading structures are often used in LEDs where the top surface is p-type, but can also be used for n-type materials.

Some or all of the LEDs described herein can be coated with one or more phosphors with the phosphors absorbing at least some of the LED light and emitting a different wavelength of light such that the LED emits a combination of light from the LED and the phosphor. In one embodiment according to the present invention the white emitting LEDs have an LED that emits light in the blue wavelength spectrum and the phosphor absorbs some of the blue light and re-emits yellow. The LEDs emit a white light combination of blue and yellow light. In other embodiments, the LED chips emit a non-white light combination of blue and yellow light as described in U.S. Pat. No. 7,213,940. In some embodiments the phosphor comprises commercially available YAG:Ce, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for white emitting LED chips include:
Tb₃₋ₓREₓO₁₂:Ce(TAG); RE=Y, Gd, La, Lu; or
Sr_{2-x-y}BaₓCa_{y}SiO₄:Eu.

LEDs that emit red light can comprise LED structures and materials that permit emission of red light directly from the active region. Alternatively, in other embodiments the red emitting LEDs can comprise LEDs covered by a phosphor that absorbs the LED light and emits a red light. Some phosphors appropriate for this structure can comprise: Lu₂O₃:Eu³⁺; (Sr₂₋ₓLaₓ) (Ce₁₋ₓEuₓ)O₄; Sr₂₋ₓEuₓCeO₄; SrTiO₃:Pr³⁺,Ga³⁺; CaAlSiN₃:Eu²⁺; and Sr₂Si₅N₈:Eu²⁺.

LEDs that are coated can be coated with a phosphor using many different methods, with one suitable method being described in U.S. patent application Ser. Nos. 11/656,759 and 11/899,790, both entitled “Wafer Level Phosphor Coating Method and Devices Fabricated Utilizing Method”, and both of which are incorporated herein by reference. Alternatively the LEDs can be coated using other methods such as electrophoretic deposition (EPD), with a suitable EPD method described in U.S. patent application No. 11/473,089 entitled “Close Loop Electrophoretic Deposition of Semiconductor Devices”, which is also incorporated herein by reference. It is understood that LED packages according to the present invention can also have multiple LEDs of different colors, one or more of which may be white emitting.

The submounts or substrates described herein can be formed of many different materials with a preferred material being electrically insulating, such as a dielectric element, with the submount being between the LED array and the component backside. The submount can comprise a ceramic such as alumina, aluminum nitride, silicon carbide, or a polymeric material such as polymide and polyester etc. In one embodiment, the dielectric material has a high thermal conductivity such as with aluminum nitride and silicon carbide. In other embodiments the submounts can comprise highly reflective material, such as reflective ceramic or metal layers like silver, to enhance light extraction from the component. In other embodiments the submount 42 can comprise a printed circuit board (PCB), alumina, sapphire or silicon or any other suitable material, such as T-Clad thermal clad insulated substrate material, available from The Bergquist Company of Chanhassen, Minn. For PCB embodiments different PCB types can be used such as standard FR-4 PCB, metal core PCB, or any other type of printed circuit board.

Referring again to FIG. 5 LED packages according to the present invention can be many different shapes and sizes, with some of the packages having sizes that conform to the currently recognized package sizes. For example, the LED packages can comprise surface mount devices and can have sizes that conform to certain recognized surface mount device (SMD) sizes such as 3528SMD, 5050SMD, 3014SMD, 3020SMD, 2835SMD, etc. The LED packages can comprise plastic lead chip carrier package (PLCC), with some embodiments being sized to conform recognized PLCC sizes. It is understood, however, that the package sizes may also be those that do not comply with recognized sizes. The cavity can have many different sizes and in some embodiments, the cavity can be 6 mm or less across its widest portion. In other embodiments it can be 4 mm or less across its widest portion, while in other embodiments is can be 3 mm or less across its widest portion.

The LED package 40 can also have emitters 44 arranged in different patterns at the base of cavity 42, with the embodiment shown having the emitters aligned in a row. The oval cavity 42 has a longitudinal axis 46 aligned with the wider portion of the cavity 42 and an orthogonal axis 48 aligned with narrower portion of the cavity 42, with the two axis crossing at the base of the cavity. In the embodiment shown the emitters are aligned on the orthogonal axis 48 and the base of the cavity 42 where the axes cross. In other embodiments the emitters can be aligned on the longitudinal axis 40 or they can be arranged in shapes around the crossing point, such as in a triangle, square shape around the crossing point. It is also understood that the emitters can be in other locations in the cavity, such as closer to an end or one of the sides.

In some embodiments, the LEDs can be arranged in relatively close proximity to one another to more closely approximate a point source. This can improve mixing of the light as well as the emitters overall FFP. In some embodiments, the emitters can be spaced approximately 500 microns or less apart. It is understood, that in other embodiments the emitters can be closer than 500 microns and in other embodiments they can be further apart. In some embodiments the spacing between the LEDs is one quarter (¼) or less of the distance across the widest portion of the cavity. In other embodiments, the spacing between the LEDs is one eight (⅛) or less of the distance across the widest portion of the cavity. In still other embodiments, the spacing between the LEDs is one tenth ( 1/10) or less of the distance across the widest portion of the cavity.

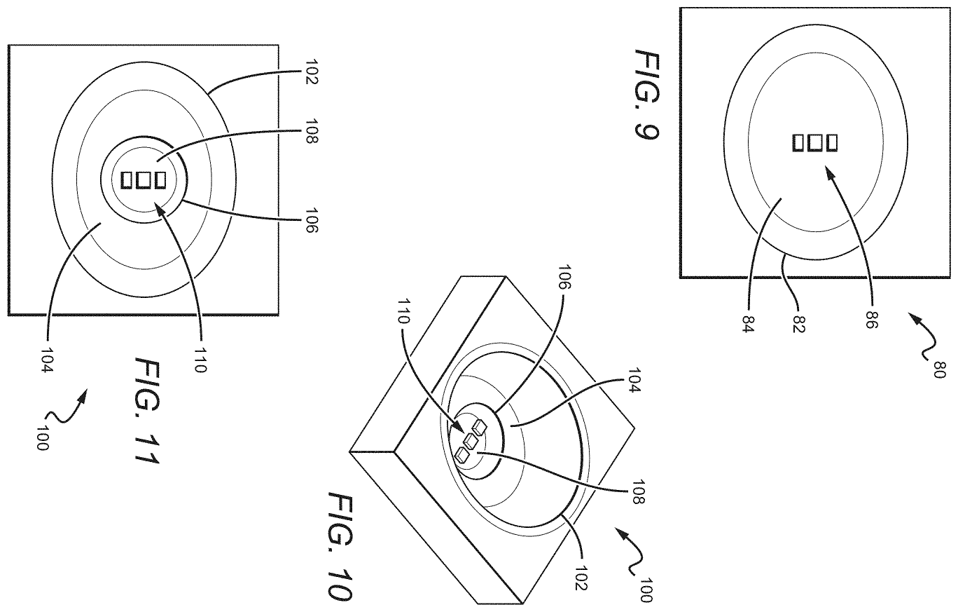

It is understood that different emitter packages according to the present invention can have cavities with different shapes and sizes. In some embodiments, the cavity can have any generally circular shape and in other embodiments the cavity can have a planar base. FIGS. 6 and 7 show another embodiment of an LED package 60 according to the present invention having a circular cavity 62 with an angled side surface 63 and a planar base 64. The package 60 further comprises emitters 66 that can be mounted at or near the center of the base 64, with the emitters 64 arranged linearly on the base. The emitters comprise red, green and blue emitting LEDs, but it is understood that the emitters can comprise any of the numbers and types of emitters described above. Light from the LEDs can reflect off the base 64 and side surface 63 of the cavity to contribute to overall LED package emission.

The package 60 can also comprise an oval shaped lens (not shown) to shape the light from the emitters in wide angle or pitch. The high point or dome of the lens can be aligned with the any of the edges of the package or can be arranged off alignment, such as diagonal. The cavity 62 can have many different sizes, with one embodiment having cavity depth of approximately 1.1 mm, and top radius of approximate 2.1 mm and base radius of approximately 1.6 mm.

FIGS. 8 and 9 show another embodiment of an LED package 80 according to the present invention having an oval cavity 82 with a planar oval base 84. Emitters 86 are mounted at or near the crossing point for the two axes of the cavity 82 as described above and shown in FIG. 5. The emitters 86 can comprise red, green and blue emitting LEDs, but it is understood that the emitters can comprise any of the numbers and types of emitters described above. The cavity can have many different oval shapes and sizes, with one embodiment having a depth of approximately 1.2 mm and oval shape having a radius at its narrow portion of approximately 2.1 mm and a radius at its widest portion of approximately 1.7 mm. The base can have a radius of approximately 1.6 mm at its narrow portion and a radius of 1.6 mm at its widest portion. It is understood that these dimensions are only exemplary and the cavity can have many different dimensions.

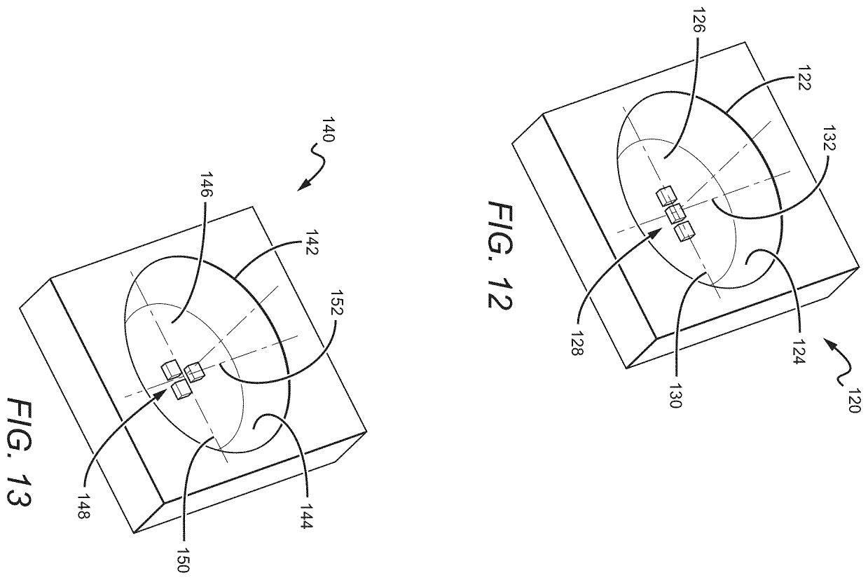

FIGS. 10 and 11 show another embodiment of LED package 100 according to the present invention having a double cavity arrangement. The LED comprises a larger oval shaped first cavity 102 with planar base 104. The LED package 100 further comprises a smaller second cavity 106 arranged in the first cavity base 104. The second cavity 106 also has a planar base 108, with emitters 110 mounted on the planar base 108. It is understood, that in other embodiments the second cavity can have a curved bottom surface instead of a planar base. The emitters can comprise any of the emitters described above that can be spaced and arranged as described above. The LED package 100 can comprise an oval lens as described herein to shape the package's emission pattern. The LED package can also be arranged with different combination of shapes for both its first and second cavities, such as oval shaped first cavity with oval shaped second cavity, circular shaped first cavity with oval shaped second cavity, and circular shaped first cavity with circular shaped second cavity.

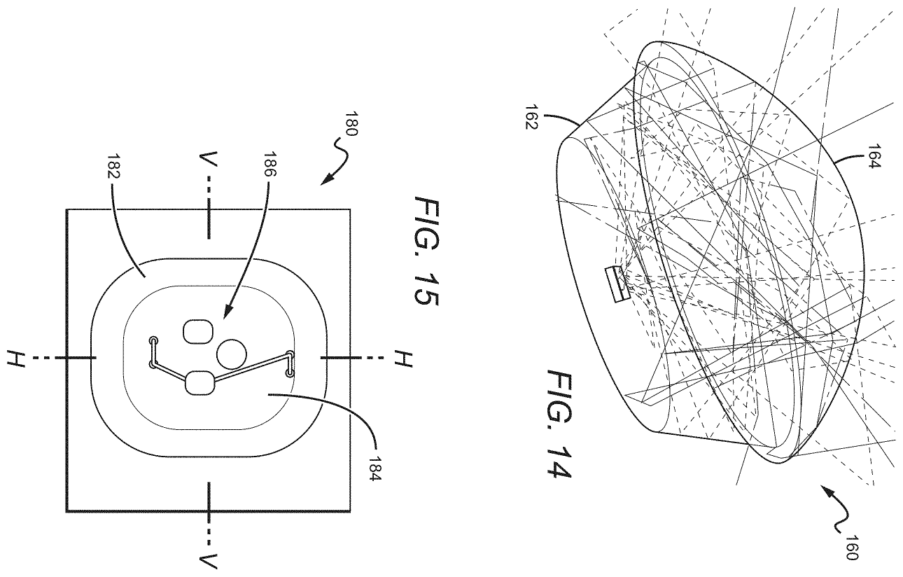

FIG. 12 shows another embodiment of an LED package 120 according to the present invention having an oval cavity 122 with an angled sidewall 124 and a planar base 126. The package 120 can also comprise emitters 128 that are mounted along the cavity's longitudinal axis 130 at the crossing point with the orthogonal axis 132. The package 120 can also comprise an oval shaped lens as described below to provide for wide angle and wide pitch emission. The cavity can be coated with reflective material as described above, and the angled sidewalls can reflect emitter light so that it contributes to useful emission from the LED package 120. Like the embodiment described above, the emitters can comprise LEDs that are placed close to one another to approximate a point light source.

FIG. 13 shows still another embodiment of an LED package 140 according to the present invention, having a cavity 142, with an angled sidewall 144, planar base 146 and emitters 148 mounted to the planar base 146. In this embodiment, the emitters 148 are clustered around the crossing point for the longitudinal and orthogonal axis 150, 152. The emitters 148 can comprise red, green and blue LEDs mounted in a triangle about the axis crossing point. The LEDs are mounted in close proximity to one another to approximate a point light source and like the embodiments above, the LED package can comprise an oval shaped lens.

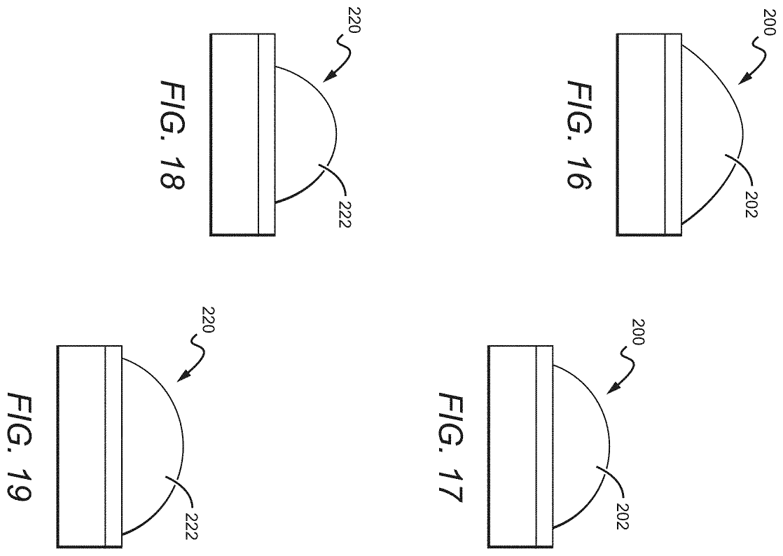

FIG. 14 shows one embodiment of a lens 160 that can be used in LED packages according to the present invention and is particularly arranged for use with a package having an oval shaped cavity with a planar base. The lenses used in the different embodiments described herein can comprise many different materials, such as an epoxy, can comprise many different refractive indexes such as 1.51, and can transmit approximately 100% of light emitted from the emitters.

The lens base 162 fits in the cavity, and the rounded upper portion 164 sits above the cavity. In some embodiments, the rounded upper portion 164 can have a dome shape, while in other embodiments the rounded upper portion 164 can have a raised portion along the longitudinal axis. In either case, the lens can shape the light from the emitters to provide a wider angle, wider pitch emission pattern compared to emitters with circular cavity and hemisphere shape.

FIG. 15 shows still another embodiment of an LED package 180 according to the present invention having a cavity 182 with an obround shape. Obround is generally known as a shape consisting of two semicircles connected by parallel lines tangent to their endpoints. This LED package 180 can have a lens (not shown) that is similar to those described above and could have a base to fit within the cavity and a generally oval shaped portion above the cavity 182. The LED package 180 has a planar base 184, with emitters 186 mounted to the planar base at or near the center point within the cavity. In the embodiment shown, the emitters can comprise red, green and blue emitting LEDs that are arranged in a triangle about the center point, but it is understood that the LED package can have different numbers of emitters that can be arranged in many different ways such as in a row, square, rectangle, etc.

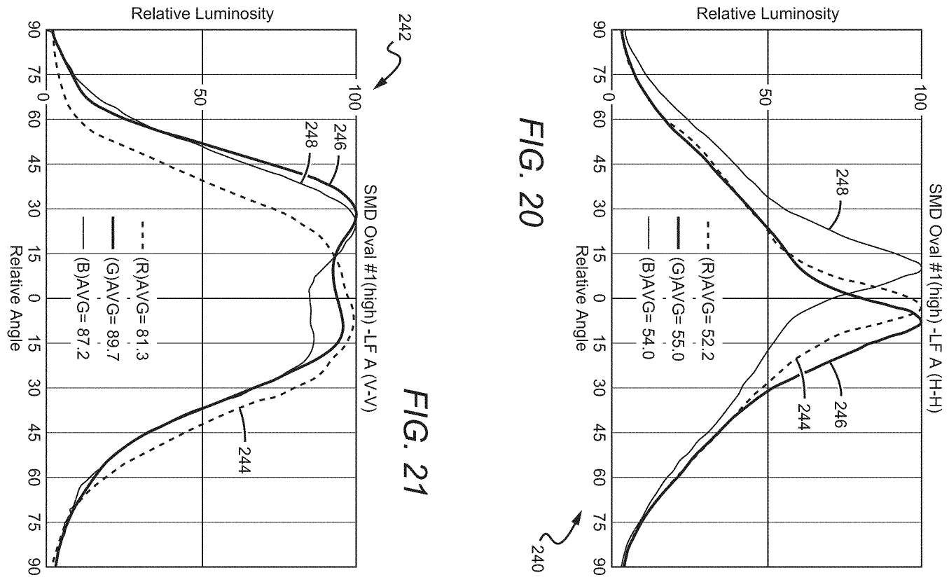

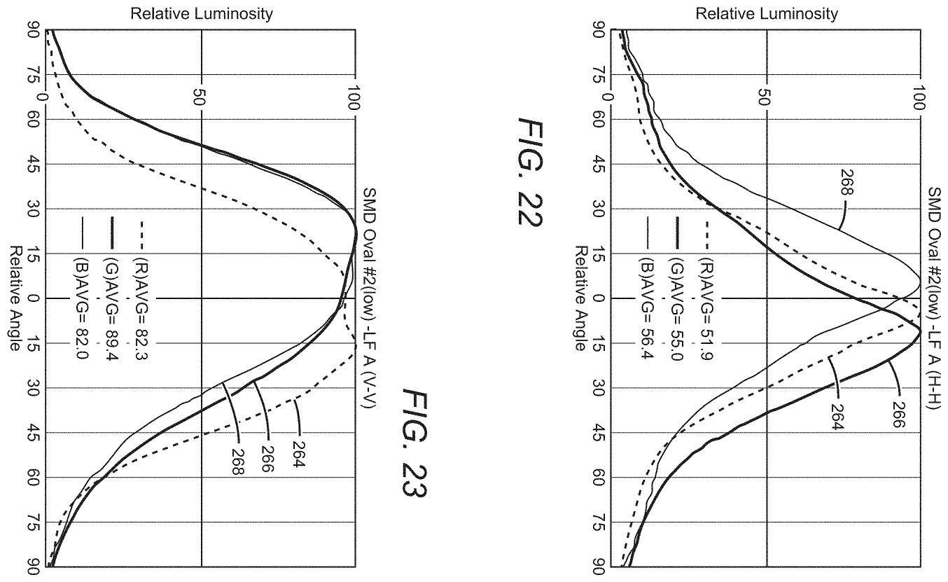

It is understood that the LED packages according to the present invention can have oval lenses with different shapes and sizes. FIGS. 16 and 17 show another embodiment of an LED packages 200 having a lens 202, and FIGS. 18 and 19 show another embodiment of an LED package 220 having a lens 222. The lens 202 for LED package 200 is higher and covers more of the top surface around the cavity compared to the lens 222 in LED package 220. This is just one of the many different size and shape variations that can be used to obtain the desired emission patterns.

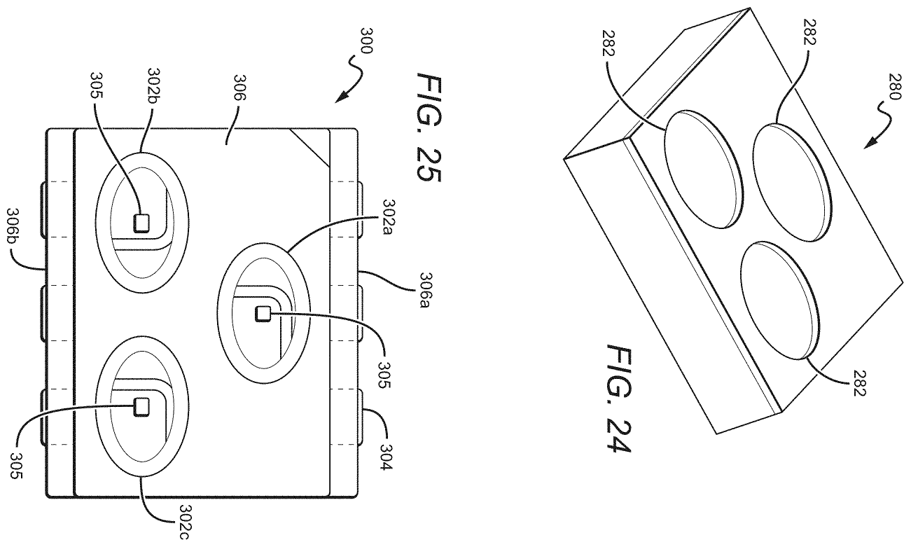

FIGS. 20 and 21 are graphs 240 and 242 showing the emission profiles for red, green and blue LEDs 244, 246, 248, for LED packages similar to the one shown in FIGS. 15 and 16 with the LEDs mounted in the LED package cavity as described above. The emission profiles in graph 240 are taken along axis H-H as shown in the LED package 180 in FIG. 15. The emission profiles in graph 242 are taken along axis V-V as shown in FIG. 15.

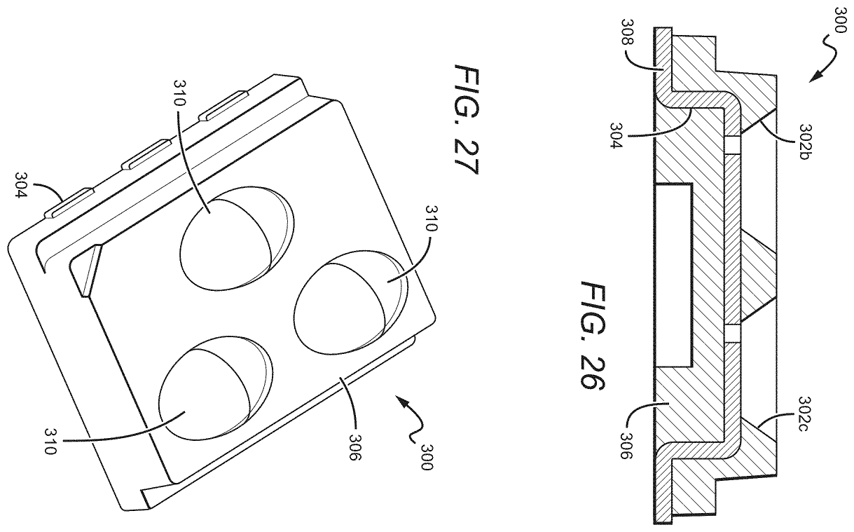

Similarly, FIGS. 22 and 23 are graphs 260 and 262 showing the emission profiles for red, green and blue LEDs 264, 266, 268 for LED packages similar to one shown in FIGS. 17 and 18 with the LED mounted in the LED package as described above. The emission profiles in graph 240 are taken along axis H-H as shown in the LED package 180 in FIG. 15. The emission profiles in graph 22 are taken along axis V-V as shown in FIG. 15. Comparison of the graphs 240, 242 to the graphs 260, 262 illustrate that different shaped oval lenses can result in variations in emission profiles.

It is understood that the lenses according to the present invention can be arranged in many different ways. The lenses can be solid and fill the cavity, or can be at least partially hollow with voids arranged in different ways. It is also understood that the lenses can have surface variations or texturing to provide the desired LED emission pattern. Examples of these surface variations can be found in PCT International Publication No. WO 2008/086682 A1, which is incorporated herein by reference.

It is understood that the present invention can be applied to LED packages arranged in many different ways beyond those described above. FIG. 24 shows another embodiment of an LED package 280 according to the present invention having multiple cavities 282, each of which can have one or more LEDs. The package can also have respective oval shaped lenses over each of the cavities 282, or a single oval shaped lens can be formed over the cavities. The cavities can be arranged close to one another to approximate a point source. This is just one the many different LED package variations according to the present invention.

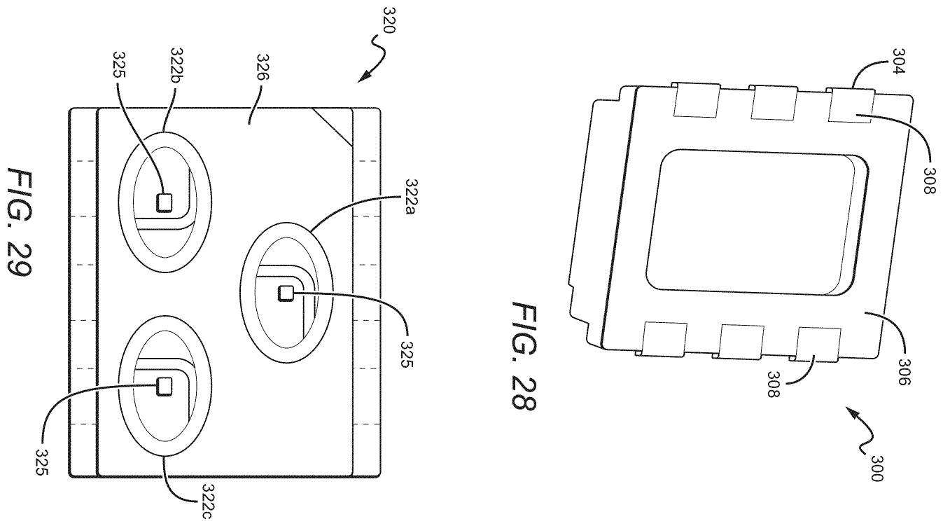

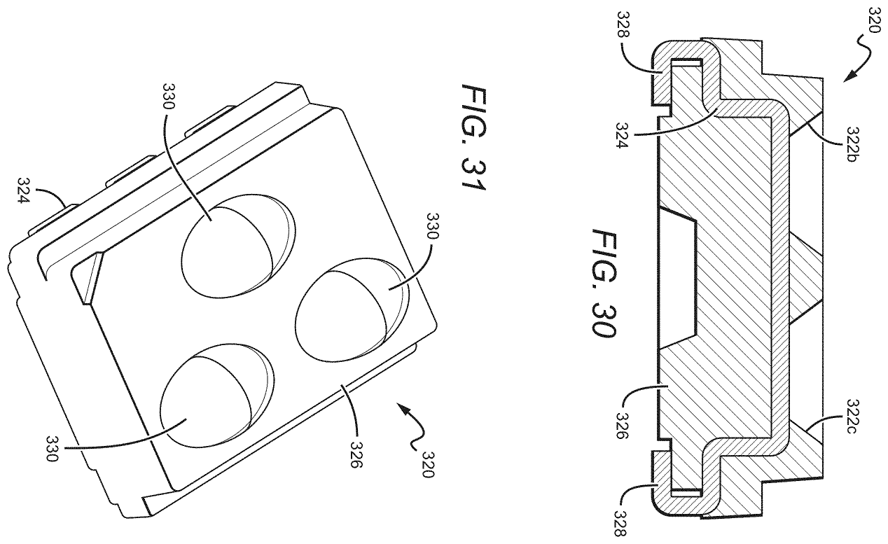

FIGS. 25-28 show another embodiment of and LED package 300 according to the present invention having multiple cavities 302a-c similar to the LED package 280 shown in FIG. 24. The LED package 300 can be arranged for surface mounting and can comprise three cavities 302a-c. It is understood that different embodiments can comprise different number of cavities such as two, four, five, or more. The cavities 302a-c can have many different shapes as the cavities described above, with the cavities 302a-c shown having an oval shape similar to the cavity shown in FIGS. 8 and 9 above. Each of the cavities 302a-c can comprise an angled side surface and a planar base for mounting an emitter, such as an LED.

The LED package 300 can have many different structures and can be fabricated using many different methods. In the embodiment shown, the LED package can comprise lead frame 304 and a body 306 that can be molded around the lead frame 304 using known methods. The molding process can also form the cavities 302a-c in the body with the lead frame accessible through the cavity. One or more emitters such as LEDs can be mounted to the exposed portion of the lead frame in each cavity. The lead frame 304 can comprise a plurality of flat pins 308 exposed at the bottom of the body 306 for surface mounting, and electrical signals applied to the pins are conducted to the emitter causing them to emit light.

It is understood that the cavities 302a-c can be arranged with many different numbers of LEDs that emit different colors of light. In different embodiments, each of the cavities 302a-c can have one or more LEDs emitting in a respective color or wavelength of light. In the embodiment shown each of the cavities can have one LED 305 that emits red, green/yellow and blue light. A red emitting LED can be mounted in cavity 302a that is adjacent and at the midpoint of side surface 306a. A blue emitting LED can be mounted in cavity 302b and a green emitting LED can be mounted in cavity 302c, with cavities 302b and 302c arranged adjacent to side surface 306b. The light from the cavities combines so that the LED package 300 emits a color combination of the light from the cavities. The intensity of the light from each of the cavities 302 can be varied based on the electrical signals applied to the lead frame 304, which allows for the LED package 300 to emit a varied color combination of light from cavities 302a-c. It is understood that in other embodiments, the cavities can have a plurality of LED emitting the same or different wavelengths of light. In one alternative embodiment, one or more of the cavities can comprise red, green/yellow and blue emitting LEDs.

The multiple cavity LED packages according to the present invention can have many different shapes and sizes, with some sized so that the light sources in the cavities are close enough to allow for efficient mixing of light from the cavities. In some embodiments, the cavities should be close enough so that the cavities approximate a point light source. In the embodiment shown, the LED package 300 has a rectangular shape, with each of the oval shaped cavities having their widest portion aligned with the longer edge of the LED package 302. In other embodiments, one or more of the cavities can be arranged in different orientations.

Some embodiments of LED packages can have side surfaces that are less than 20 mm long, and can have cavities that are less than 10 mm wide, with a depth of less than 2 mm. In other embodiments, the LED packages can have side surfaces that are less than 10 mm long, and can have cavities that are less than 5 mm wide, with a depth of less than 1 mm. In the embodiment shown, the side surfaces of the LED package can be approximately 8 mm by 5.6 mm. The cavities can be oval shaped measuring approximately 3 mm by 2 mm at the top surface of the package and having a depth of approximately 0.45 mm. In some embodiments, the widest portion of the cavities should be less than half the length of the longest side of the LED package, and the narrowest portion should be less than one third of the longest side of the package. In the embodiment shown, each of the cavities is the same size and shape, but it is understood that other embodiments can have cavities with different shapes and sizes.

As best shown in FIG. 27, each of the cavities comprises a respective oval shaped lens 310 as described above. The lenses can help shape the emission of the package to provide wide angle or wide pitch emission along an axis or centerline of the LED package compared to an LED package with circular cavity and hemispheric lens. It is understood that other embodiments can have different shaped lenses or can have lenses of different sizes.

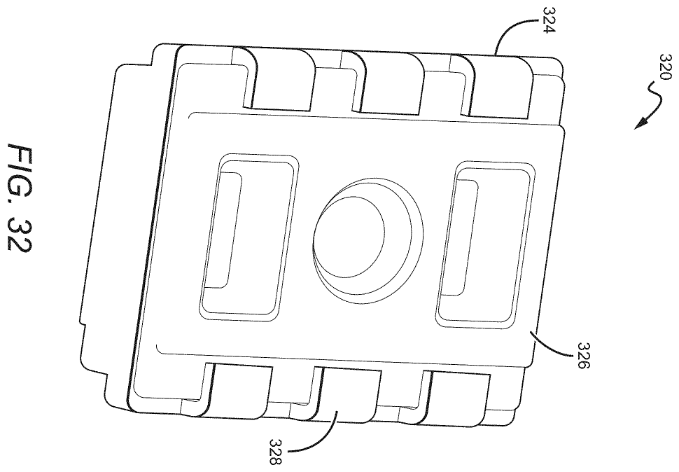

FIGS. 29-32 show another embodiment of an LED package 320 according to the present invention that is similar to the LED package 300 described above. LED package 320 comprises oval shaped cavities 322a-c, a lead frame 324, and a body 326, all of which can be arranged and formed as described above. Each of the cavities 322a-c can have one or more LEDs 325 as described above. The lead frame 324 is different from the LED package 300 and comprises pins 328 that fold under the body 326 in a known SMD arrangement. The LED package 320 can also comprise oval lenses 330 in each of the cavities as described above. This is only one of the many variations that can be included in LED packages according to the present invention.

It is understood that many other surface mount arrangements can be used to provide the desired wide angle emission, beyond the embodiments described above. It is also understood that the features of the different embodiments can be combined to achieve the desired emission profile. That is, the different LED packages in a display can have different emission profiles that combine to provide the desired display emission.

The LED packages according to the present invention can be used in many different lighting applications beyond LED displays. Some of these include, but are not limited to, street lights, architectural lights, home and office lighting, display lighting and backlighting.

Although the present invention has been described in detail with reference to certain preferred configurations thereof, other versions are possible. Therefore, the spirit and scope of the invention should not be limited to the versions described above.

We claim:

1. A light emitting diode (LED) package, comprising:
a cavity with a plurality LEDs, said cavity reflecting light from said LEDs to contribute to the emission of said package;
a lens over said cavity to shape the emission of said LEDs to a wider angle compared to emission of said LEDs without said lens; and
leads and/or wire bonds to each of said LEDs to individually control the emission of each of said LEDs with said LED package emitting different color combinations of emission from said LEDs.

2. The LED package of claim 1, wherein said lens is oval shaped.

3. The LED package of claim 1, wherein said cavity is oval shaped.

4. The LED package of claim 3, wherein said cavity has a planar base and angled side surfaces.

5. The LED package of claim 1, with said LEDs are mounted at approximately the center of said cavity.

6. The LED package of claim 1, wherein said cavity has a reflective and diffusive surface.

7. The LED package of claim 1, comprising multiple cavities.

8. The LED package of claim 4, further comprising a second cavity in the said planar base.

9. The LED package of claim 8, wherein said second cavity has angled side surfaces and a planar base.

10. The LED package of claim 1, wherein spacing between said LEDs is one quarter (¼) or less of the distance across the widest portion of the cavity.

11. A light emitting diode (LED) display, comprising:
a plurality of LED packages, at least some having a cavity with a plurality of LEDs and a lens over each said cavity to produce an emission of said LEDs that has a wider angle compared to the emission without said lens, said LED packages mounted within said display to generate a wide angle image.

12. The LED display of claim 11, wherein said lens over each said cavity is oval shaped.

13. The LED display of claim 11, wherein each said cavity is oval shaped.

14. The LED display of claim 11, wherein each said cavity has a planar base and angled side surfaces.

15. The LED display of claim 11, wherein each said cavity has a reflective and diffusive surface.

16. The LED package of claim 11, wherein each said LED package comprising multiple cavities.

17. A light emitting diode (LED) package, comprising:
a body having a plurality of cavities, with each of said cavities having an LED;
an oval shaped lens over each said cavity to shape the emission of said LEDs to a wider angle compared to emission of said LEDs without said lens, wherein the intensity of each of said LEDs is individually controllable, said LED package emitting different color combinations of light from said LEDs.

18. The LED package of claim 17, wherein one or more of said cavities is oval shaped.

19. The LED package of claim 17, wherein at least three of said plurality of LEDs comprise respective red, green and blue emitting LEDs.

20. The LED package of claim 17, wherein each said cavity has a planar base and angled side surfaces.

21. The LED package of claim 17, wherein ones of said cavities has a red emitting LED, another of said cavities has green emitting LED, and still another of said cavities has a blue emitting LED.
